(19) United States
(12) Patent Application Publication
(10) Pub. No.: US 2018/0282466 A1
(43) Pub. Date: Oct. 4, 2018

(54) POLYMER MATERIAL FOR SELF-ASSEMBLY, SELF-ASSEMBLED FILM, METHOD OF PRODUCING SELF-ASSEMBLED FILM, AND PROJECTION AND DEPRESSION PATTERN

(71) Applicant: HORIBA STEC, CO., LTD., Kyoto (JP)

(72) Inventors: Takanobu TAKEDA, Kyoto (JP); Yukio KAWAGUCHI, Kyoto (JP)

(73) Assignee: HORIBA STEC, CO., LTD., Kyoto (JP)

(21) Appl. No.: 15/521,732

(22) PCT Filed: Oct. 29, 2015
(86) PCT No.: PCT/JP2015/080616

§ 371 Date: Apr. 25, 2017

(30) Foreign Application Priority Data
Oct. 31, 2014 (JP) 2014-223348

(51) Int. Cl. C08F 297/02; C08J 5/18; C08J 7/04

(52) U.S. Cl. CPC C08F 297/02; C08J 5/18; H01L 21/0271; C08J 2353/00; C08J 7/04

(57) ABSTRACT

Provided is a polymer material for self-assembly capable of reducing defects based on poor microphase separation segments and capable of forming a fine repeating pattern, a self-assembled film, a method of producing a self-assembled film, and a projection and depression pattern. The polymer material for self-assembly according to the present invention contains a polymer compound including a constituent unit of General Formula (1) below and a constituent unit of General Formula (2) below.

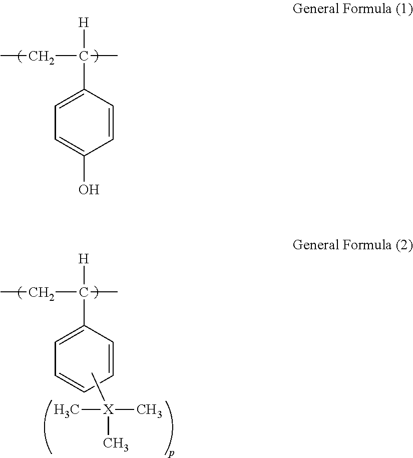

(In Formula (2), X is a carbon atom or a silicon atom, and p is an integer of 1 or more and 5 or less.)

### FIELD

The present invention relates to a polymer material for self-assembly, a self-assembled film, a method of producing a self-assembled film, and a projection and depression pattern, and specifically relates to a polymer material for self-assembly suitably used as a resist for semiconductor manufacturing, a self-assembled film, a method of producing a self-assembled film, and a projection and depression pattern.

### BACKGROUND

Pattern formation using the technique of directed self-assembly (DSA) of block copolymers has attracted attention (for example, see Patent Literature 1 to Patent Literature 4). In this directed self-assembly technique, the pattern formation by using a guide pattern or by a combination of the top-down approach of photolithography and the bottom-up approach of diblock polymer lithography enables formation of a pattern with finer half pitch compared with conventional lithography using ArF excimer laser and extreme ultraviolet (EUV).

### CITATION LIST

### Patent Literature

Patent Literature 1: Japanese Patent Publication Laid-open No. 2005-7244

Patent Literature 2: Japanese Patent Publication Laid-open No. 2005-8701

Patent Literature 3: Japanese Patent Publication Laid-open No. 2005-8882

Patent Literature 4: Japanese Patent Publication Laid-open No. 2003-218383

Patent Literature 5: Japanese Patent Publication Laid-open No. 2010-269304

Patent Literature 6: Japanese Patent Publication Laid-open No. 2011-129874

Patent Literature 7: Japanese Patent Publication Laid-open No. 2012-108369

### SUMMARY

### Technical Problem

In the fields of photonic crystals, domain size-controlling processes for organic thin-film solar cells, polymer micelles for drug delivery, and biomaterials, there is a demand for forming a projection and depression pattern with a half pitch of 10 nm or smaller. However, styrene-methyl methacrylate block copolymers used in the conventional directed self-assembly technique are limited to forming of a projection and depression pattern with a half pitch exceeding 10 nm and fail to form a projection and depression pattern with a half pitch of 10 nm or smaller. Moreover, the conventional block copolymers have limited capacity in microphase separation by self-assembly per se when forming a projection and depression pattern having a line width around 10 nm in half pitch and may cause defects based on poor microphase separation.

The present invention is made in view of the situation described above and aims to provide a polymer material for self-assembly capable of reducing defects based on poor microphase separation segments and capable of forming a fine repeating pattern, a self-assembled film, a method of producing a self-assembled film, and a projection and depression pattern.

### Solution to Problem

The inventors of the present invention have made elaborate studies in order to solve the aforementioned problem and found that the use of a polymer material for self-assembly containing a polymer compound having a constituent unit with a specific structure can reduce defects based on poor microphase separation segments and form a fine repeating pattern. This finding has led to completion of the present invention.

A polymer material for self-assembly comprising a polymer compound including a constituent unit of General Formula (1) below and a constituent unit of General Formula (2) below:

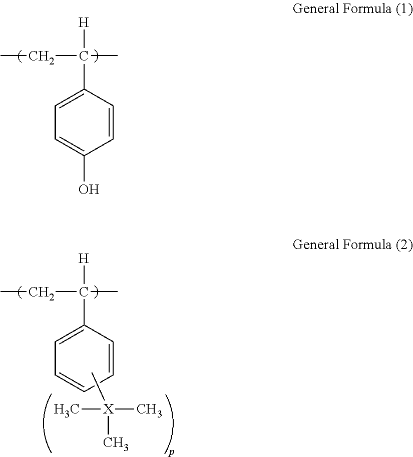

(in Formula (2), X is a carbon atom or a silicon atom, and p is an integer of 1 or more and 5 or less).

In this polymer material for self-assembly, since the polar (hydrophilic) constituent unit of General Formula (1) and the nonpolar constituent unit of General Formula (2) each have a polystyrene backbone, microphase separation performance is improved to enable reduction of defects based on poor microphase separation and enable formation of a fine repeating pattern.

It is preferable that in the polymer material for self-assembly, the polymer compound is a diblock copolymer or a triblock copolymer of the constituent unit of General Formula (1) and the constituent unit of General Formula (2) copolymerized by living anionic polymerization.

It is preferable that in the polymer material for self-assembly, the constituent unit of General Formula (2) is represented by General Formula (3) below:

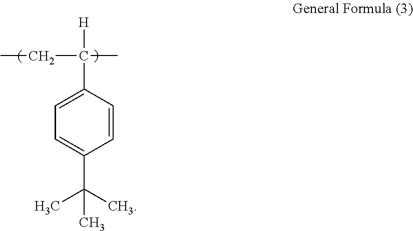

It is preferable that in the polymer material for self-assembly, the constituent unit of General Formula (2) is represented by General Formula (4) below:

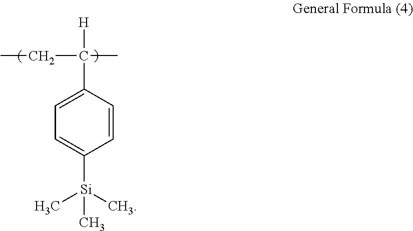

It is preferable that in the polymer material for self-assembly, the polymer compound has a weight average molecular weight of 1,000 or more and 15,000 or less.

A self-assembled film obtained using the polymer material for self-assembly.

A self-assembled film formed by applying a top coat agent on the self-assembled film.

A method of producing a self-assembled film, comprising forming a self-assembled film using the polymer material for self-assembly.

It is preferable that in the method of producing a self-assembled film, a self-assembled film is formed in a guide pattern.

It is preferable that in the method of producing a self-assembled film, further comprising a step of applying a top coat agent on the self-assembled film.

A projection and depression pattern obtained by etching the self-assembled film

### Advantageous Effects of Invention

The present invention can achieve a polymer material for self-assembly capable of reducing defects based on poor microphase separation segments and capable of forming a fine repeating pattern, a self-assembled film, a method of producing a self-assembled film, and a projection and depression pattern.

### BRIEF DESCRIPTION OF DRAWINGS

FIG. 1 is a diagram illustrating a GPC chart according to Synthesis Example 1 of the present invention.

FIG. 2 is a diagram illustrating a SAXS data chart of a self-assembled film according to Example of the present invention.

FIG. 3 is an optical coherence photograph of the self-assembled film according to Example of the present invention.

### DESCRIPTION OF EMBODIMENTS

An embodiment of the present invention will be described in details below.

A polymer material for self-assembly according to the present invention contains a polymer compound including a constituent unit of General Formula (1) below and a constituent unit of General Formula (2) below.

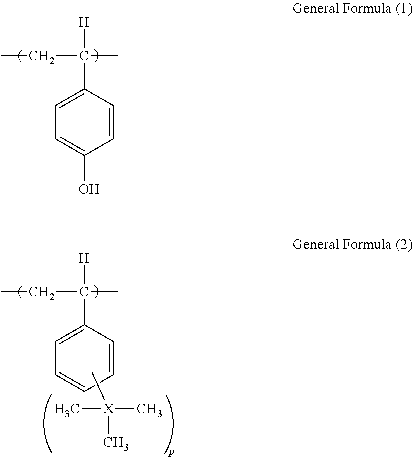

(In Formula (2), X is a carbon atom or a silicon atom, and p is an integer of 1 or more and 5 or less.)

In this polymer material for self-assembly, since the polar (hydrophilic) constituent unit of General Formula (1) above and the nonpolar constituent unit of General Formula (2) each have a polystyrene backbone, microphase separation performance is improved to enable reduction of defects based on poor microphase separation and enable formation of a fine repeating pattern.

As the polymer compound, a copolymer of a constituent unit having a 4-hydroxystyrene backbone represented by General Formula (1) above and a constituent unit having a tertiary carbon- or tertiary silicon-substituted styrene backbone represented by General Formula (2) above is used. This copolymer may be a diblock copolymer or may be a triblock copolymer.

A variety of compounds can be used as the constituent unit of General Formula (2) above without impairing the effects of the present invention. Among those, in terms of uniformity and regularity of the pattern of microdomain structure by self-assembly, those represented by General Formulae (5) below are preferable.

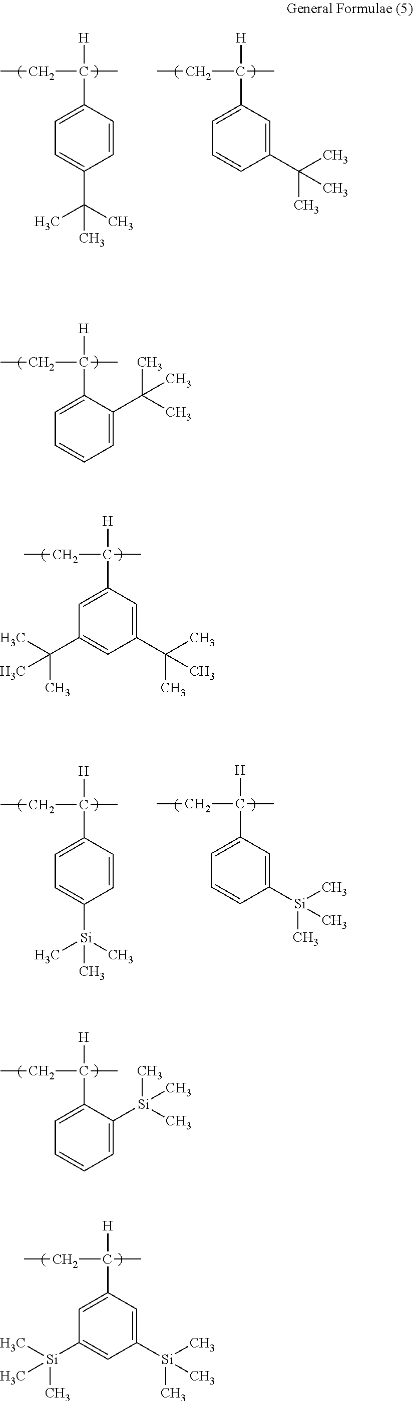

As the polymer compound, those in which the constituent unit of General Formula (2) above is represented by General Formula (3) below are preferable. This formulation adequately reduces the polarity of the nonpolar constituent unit of the polymer compound, thereby improving uniformity and regularity of the pattern of microdomain structure formed by self-assembly.

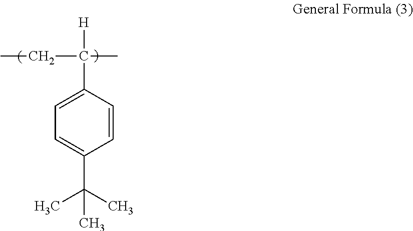

As the polymer compound, preferably, the constituent unit of General Formula (2) above is represented by General Formula (4) below. This formulation adequately reduces the polarity of the nonpolar constituent unit of the polymer compound, thereby improving uniformity and regularity of the pattern of microdomain structure formed by self-assembly.

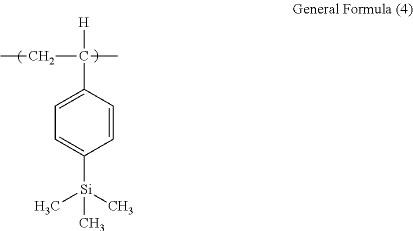

As the polymer compound, a diblock copolymer or a triblock copolymer of the constituent unit of General Formula (1) above and the constituent unit of General Formula (2) above may be used. When a diblock copolymer is used as the polymer compound, the ratio of the constituent units is not limited and may be selected appropriately depending on the kind of microdomain structure to be formed by self-assembly.

When a diblock copolymer is used as the polymer compound, the ratio of the constituent units is as follows. The ratio (m:n) between the constituent unit (m) of General Formula (1) above and the constituent unit (n) of General Formula (2) above is preferably in a range of m:n=8:2 to 2:8 in terms of improvement in uniformity and regularity of the pattern of microdomain structure formed by self-assembly. For example, when a lamellar structure is formed by self-assembly, the ratio (m:n) between the constituent unit (m) of General Formula (1) and the constituent unit (n) of General Formula (2) above is preferably set in a range of m:n=4:6 to 6:4, more preferably m:n=5:5, in terms of improvement in uniformity and regularity of the pattern of microdomain structure formed by self-assembly. When a cylindrical structure is formed by self-assembly, the ratio (m:n) between the constituent unit (m) of General Formula (1) above and the constituent unit (n) of General Formula (2) above is preferably m:n=3:7 or 7:3 in terms of improvement in uniformity and regularity of the pattern of microdomain structure formed by self-assembly. In this case, the constituent unit with a smaller proportion forms the internal film of the cylindrical structure.

The polymer compound preferably has a weight average molecular weight of 1,000 or more, more preferably 3,000 or more, further preferably 4,000 or more, and preferably 15,000 or less, more preferably 12,000 or less, further preferably 10,000 or less, in terms of improvement in uniformity and regularity of the pattern of microdomain structure formed by self-assembly. With the weight average molecular weight of 1,000 or more, self-assembly proceeds to yield a self-assembled film having a microdomain structure formed therein. With the molecular weight of 15,000 or less, the hydrogen bonds of the hydroxy group of the polymer compound act adequately, so that self-assembly occurs without insufficiency in the X parameter between blocks to form a microdomain structure, thereby achieving a pattern size of 10 nm or smaller.

In the present invention, the weight average molecular weight is measured by gel permeation chromatography (GPC) (in terms of polystyrene). The weight average molecular weight by GPC is specifically measured using a GPC system (trade name: HLC-8220GPC manufactured by TOSOH CORPORATION) with a column (trade name: GPC column TSKgel Super HZ2000 HZ3000 manufactured by TOSOH CORPORATION) and a mobile phase (THF) at a column temperature of 30° C., and calculated using the calibration curve of standard polystyrene.

The polymer compound preferably has a molecular-weight distribution (degree of distribution: Mw/Mn) of 1.0 or more, more preferably 1.02 or more, and preferably 1.1 or less, more preferably 1.06 or less. When the molecular-weight distribution (Mw/Mn) is 1.0 or more and 1.1 or less, low-molecular-weight polymers and high-molecular-weight polymers can be reduced sufficiently, thereby improving uniformity and regularity of the pattern of microdomain structure formed by self-assembly.

The polymer compound is preferably a diblock copolymer or a triblock copolymer of the constituent unit of General Formula (1) and the constituent unit of General Formula (2) copolymerized by living anionic polymerization. Since the polymer compound is obtained through copolymerization by living anionic polymerization, the molecular-weight distribution (Mw/Mn) can be significantly narrowed, and the polymer compound having a desired weight average molecular weight can be obtained accurately. This constitution can improve uniformity and regularity of the pattern of microdomain structure formed by self-assembly.

The polymer compound can be produced by any method that can copolymerize the constituent unit of General Formula (1) above and the constituent unit of General Formula (2) above. Examples of the polymerization process for obtaining the polymer compound include living anionic polymerization, living cationic polymerization, living radical polymerization, and coordination polymerization using an organic metal catalyst. Among those, living anionic polymerization is preferable, which allows living polymerization with less deactivation and side reaction of polymerization.

In living anionic polymerization, a monomer for polymerization and an organic solvent subjected to deoxidation and dehydration process are used. Examples of the organic solvent include hexane, cyclohexane, toluene, benzene, diethyl ether, and tetrahydrofuran. In living anionic polymerization, polymerization is performed by adding a required amount of anionic species to these organic solvents and thereafter adding a monomer at the appropriate timing. Examples of the anionic species include organic metals such as alkyllithiums, alkylmagnesium halides, naphthalene sodium, and alkylated lanthanoid-based compounds. Among those, s-butyllithium and butylmagnesium chloride are preferable as the anionic species, because a substituted styrene is copolymerized as a monomer in the present invention. The polymerization temperature in living anionic polymerization is preferably in a range of −100° C. or higher to 0° C. or lower, more preferably −70° C. or higher to −30° C. or lower, in terms of easiness of control of polymerization.

In the method of producing the polymer compound, for example, a monomer of substituted styrene with a protected phenolic hydroxy group such as 4-ethoxyethoxystyrene is block-copolymerized by living anionic polymerization under the conditions above to synthesize a block copolymer, and the phenolic hydroxy group of the resultant polymer compound is deprotected using an acid catalyst such as oxalic acid. Examples of the protecting group for the phenolic hydroxy group during polymerization include a t-butyl group and trialkylsilyl groups. When another monomer having an ether segment or ester segment is to be copolymerized in the polymer compound, the phenolic hydroxy group can be obtained by selectively performing deprotection through adjustment of acidity during a deprotection reaction and a deprotection reaction under an alkaline condition.

The self-assembled film according to the present invention is obtained by applying the aforementioned polymer material for self-assembly dissolved in an organic solvent. The organic solvent for dissolving the polymer material for self-assembly is any solvent that yields a self-assembled film, and examples include butyl acetate, amyl acetate, cyclohexyl acetate, 3-methoxybutyl acetate, methyl ethyl ketone, methyl amyl ketone, cyclohexanone, cyclopentanone, 3-ethoxy ethyl propionate, 3-ethoxy methyl propionate, 3-methoxy methyl propionate, methyl acetoacetate, ethyl acetoacetate, diacetone alcohol, methyl pyruvate, ethyl pyruvate, propylene glycol monomethyl ether, propylene glycol monoethyl ether, propylene glycol monomethyl ether propionate, propylene glycol monoethyl ether propionate, ethylene glycol monomethyl ether, ethylene glycol monoethyl ether, diethylene glycol monomethyl ether, diethylene glycol monoethyl ether, 3-methyl-3-methoxy butanol, N-methyl pyrrolidone, dimethyl sulfoxide, γ-butyrolactone, propylene glycol methyl ether acetate, propylene glycol ethyl ether acetate, propylene glycol propyl ether acetate, methyl lactate, ethyl lactate, propyl lactate, and tetramethylene sulfone. These solvents may be used singly or may be used in combination of two or more.

As the organic solvent for dissolving the polymer material for self-assembly, propylene glycol alkyl ether acetates and alkyl ester lactates are preferable. Examples of the propylene glycol alkyl ether acetates include those including a C₁₋₄ alkyl group. Examples of such an alkyl group include methyl groups, ethyl groups, propyl groups, and butyl groups. Among those, methyl groups and ethyl groups are preferable. Propylene glycol alkyl ether acetates have three isomers in accordance with a combination of substitution positions including 1,2-substitution and 1,3-substitution. These isomers may be used singly or may be used in combination of two or more.

Examples of the alkyl ester lactate include those including a C₁₋₄ alkyl group. Examples of such an alkyl group include methyl groups, ethyl groups, propyl groups, and butyl groups. Among those, methyl groups and ethyl groups are preferable.

For example, when a propylene glycol alkyl ether acetate is used, the concentration of the organic solvent is preferably set such that the amount of the propylene glycol alkyl ether acetate is 50% by mass or more with respect to the total mass of the organic solvent. When an alkyl ester lactate is used, the amount of the alkyl ester lactate is preferably 50% by mass or more with respect to the total mass of the organic solvent. When a solvent mixture of the propylene glycol alkyl ether acetate and the alkyl ester lactate is used as the organic solvent, the total amount of the solvent mixture is preferably 50% by mass or more with respect to the total mass of the organic solvent. When this solvent mixture is used, it is preferable that the proportion of the propylene glycol alkyl ether acetate is 60% by mass or more and 95% by mass or less and the proportion of the alkyl ester lactate is 5% by mass or more and 40% by mass or less. With 60% by mass or more of propylene glycol alkyl ether acetate, the coating properties of the self-assembly material are excellent. With 95% by mass or less, the solubility of the self-assembly material is improved.

The solution of the self-assembly material in the organic solvent has any concentration that can yield a self-assembled film by a conventionally known film formation process. For example, the amount of the organic solvent is preferably 5,000 parts by mass or more and 50,000 parts by mass or less, more preferably 7,000 parts by mass or more and 30,000 parts by mass or less, with respect to 100 parts by mass of the solid component of the self-assembly material.

The self-assembly material can be applied by any process that can yield a self-assembled film. Examples of the process include spin coating, dipping, flexography, inkjet printing, spraying, potting, and screen printing.

For the self-assembled film, a top coat agent may be applied on the self-assembled film. This process seals and protects the self-assembled film and therefore improves the handling and the weather resistance of the self-assembled film. Examples of the top coat agent include polyester-based top coat agents, polyamide-based top coat agents, polyurethane-based top coat agents, epoxy-based top coat agents, phenol-based top coat agents, (meth)acryl-based top coat agents, polyvinyl acetate-based top coat agents, polyolefin-based top coat agents such as polyethylene or polypropylene, and cellulose-based top coat agents. The coating amount of the top coat agent (in terms of solid content) is preferably 3 g/m² or more and 7 g/m or less. The top coat agent can be applied on the self-assembled film by a conventionally known application process.

The self-assembled film may be formed in a guide pattern. In this case, for example, the self-assembled film can be formed by applying a solution of the polymer material for the self-assembled film on a silicon substrate with a guide pattern. Then, annealing at 200° C. or higher and 300° C. or lower for 5 minutes or longer to 1 hour or shorter yields a pattern of self-assembled microdomain structure on the silicon substrate. The resultant pattern of microdomain structure is etched by oxygen plasma gas to obtain a projection and depression pattern with a half pitch of 10 nm or smaller and a projection and depression pattern with a half pitch of 5 nm or smaller, such as a line pattern and a contact hole pattern.

As described above, in the polymer material for self-assembly according to the present invention, since the polar (hydrophilic) constituent unit of General Formula (1) above and the nonpolar constituent unit of General Formula (2) above each have a polystyrene backbone, microphase separation performance is improved to enable reduction of defects based on poor microphase separation and formation of a fine repeating pattern. An organic solvent solution of the resultant polymer material for self-assembly is then applied on, for example, a silicon substrate, followed by baking and annealing to obtain a fine (for example, half pitch of 10 nm or smaller) projection and depression pattern of microdomain structure formed by self-assembly. Thus, the polymer material for self-assembly according to the present invention can form a projection and depression pattern with a half pitch of 10 nm or smaller, which has been difficult to form with conventional ArF excimer laser and EUV lithography, and therefore can be used suitably as an etching mask material for semiconductor manufacturing and developed into various fields, for example, applications to photonic crystals, the use for domain size-controlling processes for organic thin-film solar cells, polymer micelles for drug delivery, and biomaterials.

### EXAMPLES

Examples and Comparative Examples will be described below to clarify the effects of the present invention. It is noted that the present invention is not limited by Examples and Comparative Examples below.

### Synthesis Example 1

After a 5 L-anionic polymerization reactor was dried under reduced pressure, 4,500 g of a tetrahydrofuran (THF) solution subjected to a distillation dehydration process with sodium metal and benzophenone was poured under reduced pressure and cooled to −70° C. Next, to the cooled THF solution, 9.5 mL of s-butyllithium (cyclohexane solution: 2.03 mol/L) was poured, and thereafter 171.6 g of 4-t-butylstyrene subjected to a distillation dehydration process with sodium metal was added dropwise. Then, the rate of dropwise addition was adjusted such that the internal temperature of the reaction solution did not reach −60° C. or higher. After completion of the dropwise addition, the reaction was further allowed to proceed for 30 minutes. Subsequently, 117.6 g of 4-ethoxyethoxystyrene subjected to a distillation dehydration process with sodium metal was further added dropwise and allowed to react for 30 minutes. Next, after 30 g of methanol was poured to stop the reaction, the temperature of the reaction solution was increased to room temperature, and the resultant reaction solution was concentrated under reduced pressure. Then, 335 g of acetone was poured for re-dissolution to obtain a diblock polymer solution. Next, this diblock polymer solution was added to 18.5 L of ultrapure water to precipitate and wash the diblock polymer. Next, the solid component was filtered off and dried under reduced pressure at 50° C. for 20 hours to yield 288.4 g of white powder solid of the diblock polymer.

Next, the resultant diblock polymer dissolved in 1,730 g of THF was poured into a 5 L-reaction vessel, to which 1,000 g of methanol and 5.76 g of oxalic acid were added to perform a deprotection reaction under nitrogen atmosphere at 40° C. for 20 hours. Subsequently, the reaction solution was cooled to the vicinity of room temperature and subjected to a neutralization reaction with addition of 11.5 g of pyridine. Next, the resultant reaction solution was concentrated under reduced pressure, and 1,180 g of acetone was poured for re-dissolution. Next, the diblock polymer solution after deprotection was added to 18.5 L of ultrapure water to precipitate and wash the diblock polymer. Subsequently, the solid component was filtered off and dried under reduced pressure at 50° C. for 20 hours to yield 265.3 g of white powder solid of a diblock polymer (1).

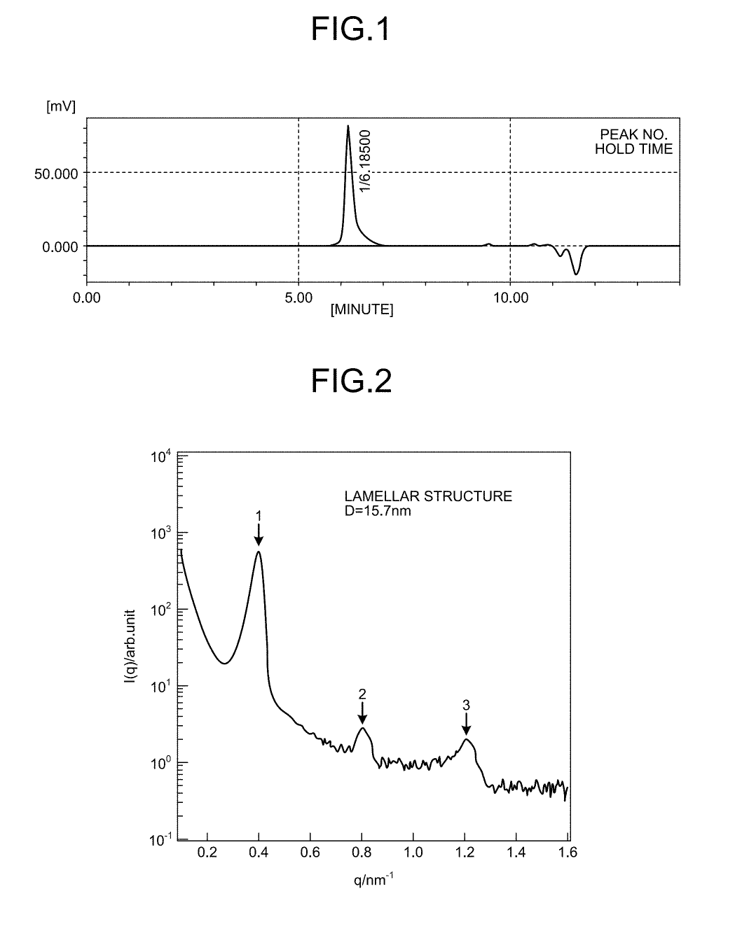

For the resultant diblock polymer (1), the composition ratio (molar ratio) of the diblock polymer was calculated by 1H-NMR as follows, and the weight average molecular weight and the molecular-weight distribution were measured by gel permeation chromatography (GPC). The measurement device and the measurement results are listed below. The GPC chart is illustrated in FIG. 1.

<1H-NMR>

Measurement device: superconducting FT-NMR (trade name: JNM-AL400 manufactured by JEOL Ltd.)

Solvent used: D-DMSO

Reference material: tetramethylsilane 0.1 wt %

The composition ratio of the diblock polymer was calculated from the peak area ratio of the hydroxy group-derived peak (8.7 PPM-9.2 PPM), the benzene ring-derived peak (6.0 PPM-7.0 PPM), and the like.
Composition ratio of diblock polymer 4-t-butylstyrene:4-hydroxystyrene=51.6:48.4 <GPC>
Measurement device: high-speed GPC system (trade name: HLC-8220GPC manufactured by TOSOH CORPORATION) Developing solvent: THF
Molecular weight determination method: in terms of standard polystyrene
Weight average molecular weight (Mw)=12,100
Molecular-weight distribution (Mw/Mn)=1.05

### Synthesis Example 2

After a 5 L-anionic polymerization reactor was dried under reduced pressure, 4,500 g of a tetrahydrofuran (THF) solution subjected to a distillation dehydration process with sodium metal and benzophenone was poured under reduced pressure and cooled to −70° C. Next, to the cooled THF solution, 22 mL of s-butyllithium (cyclohexane solution: 2.03 mol/L) was poured, and 116.1 g of 4-t-butylstyrene subjected to a distillation dehydration process with sodium metal was added dropwise. Next, the rate of dropwise addition was adjusted such that the internal temperature of the reaction solution did not reach −60° C. or higher. After completion of the dropwise addition, the reaction was further allowed to proceed for 30 minutes. Next, 151.9 g of 4-ethoxyethoxystyrene subjected to a distillation dehydration process with sodium metal was further added dropwise and allowed to react for 30 minutes. Next, after 30 g of methanol was poured to stop the reaction, the temperature of the reaction solution was increased to room temperature, and the resultant reaction solution was concentrated under reduced pressure. Next, after 335 g of acetone was poured to redissolve the diblock polymer, the diblock polymer solution was added to 18.5 L of ultrapure water to precipitate and wash the diblock polymer. Next, the solid component was filtered off and dried under reduced pressure at 50° C. for 20 hours to yield 252.6 g of white powder solid of the diblock polymer.

Next, after the resultant diblock polymer dissolved in 1,510 g of THF was poured into a 5 L-reaction vessel, 882 g of methanol and 5.04 g of oxalic acid were added to perform a deprotection reaction under nitrogen atmosphere at 40° C. for 20 hours. Next, the reaction solution was cooled to the vicinity of room temperature and subsequently subjected to a neutralization reaction with addition of 10.1 g of pyridine. Next, after the resultant deprotected reaction solution was concentrated under reduced pressure, 1,180 g of acetone was poured to redissolve the diblock polymer. Next, the diblock polymer solution after deprotection was added to 18.5 L of ultrapure water to precipitate and wash the diblock polymer. Next, the solid component was filtered off and thereafter dried under reduced pressure at 50° C. for 20 hours to yield 224.8 g of white powder solid of a diblock polymer (2).

For the resultant diblock polymer (2), the composition ratio of the diblock polymer, and the weight average molecular weight and the molecular-weight distribution were measured in the same manner as in Example 1. The measurement results are listed below.
Diblock polymer composition ratio 4-t-butylstyrene:4-hydroxystyrene=51.1:48.9
Weight average molecular weight (Mw)=7,500
Molecular-weight distribution (Mw/Mn)=1.04

### Synthesis Example 3

After a 5 L-anionic polymerization reactor was dried under reduced pressure, 4,500 g of a tetrahydrofuran (THF) solution subjected to a distillation dehydration process with sodium metal and benzophenone was poured under reduced pressure and cooled to −70° C. Subsequently, to the cooled THF solution, 25 mL of s-butyllithium (cyclohexane solution: 2.03 mol/L) was poured, and thereafter 103.1 g of 4-trimethylsilylstyrene subjected to a distillation dehydration process with sodium metal was added dropwise. The rate of dropwise addition was adjusted such that the internal temperature of the reaction solution did not reach −60° C. or higher. After completion of the dropwise addition, the reaction was allowed to proceed for 30 minutes. Subsequently, 164.9 g of 4-ethoxyethoxystyrene subjected to a distillation dehydration process with sodium metal was further added dropwise and allowed to react for 30 minutes. Next, after 30 g of methanol was poured to stop the reaction, the temperature of the reaction solution was increased to room temperature, and the resultant reaction solution was concentrated under reduced pressure. Subsequently, 350 g of acetone was poured to redissolve the diblock polymer. This diblock polymer solution was added to 18.5 L of ultrapure water to precipitate and wash the diblock polymer. Subsequently, the solid component was filtered off and dried under reduced pressure at 50° C. for 20 hours to yield 266.5 g of white powder solid of the diblock polymer.

Next, after the resultant diblock polymer dissolved in 1,600 g of THF was poured into a 5 L-reaction vessel, 930 g of methanol and 5.32 g of oxalic acid were added to perform a deprotection reaction under nitrogen atmosphere at 40° C. for 20 hours. Next, the reaction solution was cooled to the vicinity of room temperature and then subjected to a neutralization reaction with addition of 10.6 g of pyridine. The resultant deprotected reaction solution was concentrated under reduced pressure, and 1,180 g of acetone was poured to redissolve the diblock polymer. This diblock polymer solution after deprotection was added to 18.5 L of ultrapure water to precipitate and wash the diblock polymer. Subsequently, the solid component was filtered off and dried under reduced pressure at 50° C. for 20 hours to yield 226.1 g of white powder solid of a diblock polymer (3).

For the resultant diblock polymer (3), the composition ratio of the diblock polymer, and the weight average molecular weight and the molecular-weight distribution were measured in the same manner as in Example 1. The measurement results are listed below.
Diblock polymer composition ratio 4-trimethylsilylstyrene:4-hydroxystyrene=50.9:49.1
Weight average molecular weight (Mw)=5,700
Molecular-weight distribution (Mw/Mn)=1.05

### Comparative Synthesis Example 1

After a 5 L-anionic polymerization reactor was dried under reduced pressure, 4,500 g of a tetrahydrofuran (THF) solution subjected to a distillation dehydration process with sodium metal and benzophenone was poured under reduced pressure and cooled to −70° C. Next, to the cooled THF solution, 8.5 mL of s-butyllithium (cyclohexane solution: 2.03 mol/L) was poured, and thereafter 153.9 g of styrene subjected to a distillation dehydration process with sodium metal was added dropwise. The rate of dropwise addition was adjusted such that the internal temperature of the reaction solution did not reach −60° C. or higher. Next, after completion of the dropwise addition, the reaction was allowed to proceed for 30 minutes. Subsequently, 3.8 g of diphenylethylene subjected to a distillation dehydration process with sodium metal was added dropwise and allowed to react for 30 minutes. Next, after 148.1 g of methacrylic acid methyl ester subjected to a distillation dehydration process with calcium hydroxide and dibutylmagnesium was added dropwise, the temperature of the polymerization solution was increased to 0° C., and 30 g of methanol was poured to stop the reaction. Next, after the temperature of the reaction solution was increased to room temperature and the resultant reaction solution was concentrated under reduced pressure, 380 g of acetone was poured to redissolve the diblock polymer. This diblock polymer solution was added to 18.5 L of ultrapure water to precipitate and wash the diblock polymer. Subsequently, the solid component was filtered off and dried under reduced pressure at 50° C. for 20 hours to yield 286.7 g of white powder solid of a diblock polymer (4).

For the resultant diblock polymer (4), the composition ratio of the diblock polymer, and the weight average molecular weight and the molecular-weight distribution were measured in the same manner as in Example 1. The measurement results are listed below.
Diblock polymer composition ratio styrene:methacrylic acid methyl ester=51.0:49.0
Weight average molecular weight (Mw)=30,700
Molecular-weight distribution (Mw/Mn)=1.05

### Comparative Synthesis Example 2

After a 5 L-anionic polymerization reactor was dried under reduced pressure, 4,500 g of a tetrahydrofuran (THF) solution subjected to a distillation dehydration process with sodium metal and benzophenone was poured under reduced pressure and cooled to −70° C. Next, to the cooled THF solution, 12 mL of s-butyllithium (cyclohexane solution: 2.03 mol/L) was poured, and thereafter 100.5 g of styrene subjected to a distillation dehydration process with sodium metal was added dropwise. The rate of dropwise addition was adjusted such that the internal temperature of the reaction solution did not reach −60° C. or higher. After completion of the dropwise addition, the reaction was allowed to proceed for 30 minutes. Subsequently, 5.3 g of diphenylethylene subjected to a distillation dehydration process with sodium metal was added dropwise and allowed to react for 30 minutes. Next, after 96.8 g of methacrylic acid methyl ester subjected to a distillation dehydration process with calcium hydroxide and dibutylmagnesium was added dropwise, the temperature of the polymerization solution was increased to 0° C., and 30 g of methanol was poured to stop the reaction. Next, after the temperature of the reaction solution was increased to room temperature and the resultant reaction solution was concentrated under reduced pressure, 240 g of acetone was poured to redissolve the diblock polymer. This diblock polymer solution was added to 18.5 L of ultrapure water to precipitate and wash the diblock polymer. Subsequently, the solid component was filtered off and dried under reduced pressure at 50° C. for 20 hours to yield 187.9 g of white powder solid of a diblock polymer (5).

For the resultant diblock polymer (5), the composition ratio of the diblock polymer, and the weight average molecular weight and the molecular-weight distribution were measured in the same manner as in Example 1. The measurement results are listed below.
Diblock polymer composition ratio styrene:methacrylic acid methyl ester=51.8:48.2
Weight average molecular weight (Mw)=15,200
Molecular-weight distribution (Mw/Mn)=1.04

### Comparative Synthesis Example 3

After a 5 L-anionic polymerization reactor was dried under reduced pressure, 4,500 g of a tetrahydrofuran (THF) solution subjected to a distillation dehydration process with sodium metal and benzophenone was poured under reduced pressure and cooled to −70° C. Next, to the cooled THF solution, 14 mL of s-butyllithium (cyclohexane solution: 2.03 mol/L) was poured, and thereafter 100.7 g of styrene subjected to a distillation dehydration process with sodium metal was added dropwise. The rate of dropwise addition was adjusted such that the internal temperature of the reaction solution did not reach −60° C. or higher. After completion of the dropwise addition, the reaction was allowed to proceed for 30 minutes. Subsequently, 5.2 g of diphenylethylene subjected to a distillation dehydration process with sodium metal was added dropwise and allowed to react for 30 minutes. Next, after 96.4 g of methacrylic acid methyl ester subjected to a distillation dehydration process with calcium hydroxide and dibutylmagnesium was added dropwise, the temperature of the polymerization solution was increased to 0° C., and 30 g of methanol was poured to stop the reaction. Next, after the temperature of the reaction solution was increased to room temperature and the resultant reaction solution was concentrated under reduced pressure, 240 g of acetone was poured to redissolve the diblock polymer. This diblock polymer solution was added to 18.5 L of ultrapure water to precipitate and wash the diblock polymer. The solid component was filtered off and then dried under reduced pressure at 50° C. for 20 hours to yield 190.0 g of white powder solid of a diblock polymer (6).

For the resultant diblock polymer (6), the composition ratio of the diblock polymer, and the weight average molecular weight and the molecular-weight distribution were measured in the same manner as in Example 1. The measurement results are listed below.
Diblock polymer composition ratio styrene:methacrylic acid methyl ester=50.8:49.2
Weight average molecular weight (Mw)=12,200
Molecular-weight distribution (Mw/Mn)=1.05

### Examples 1 to 3, Comparative Examples 1 to 3

<Preparation of Self-Assembled Film>

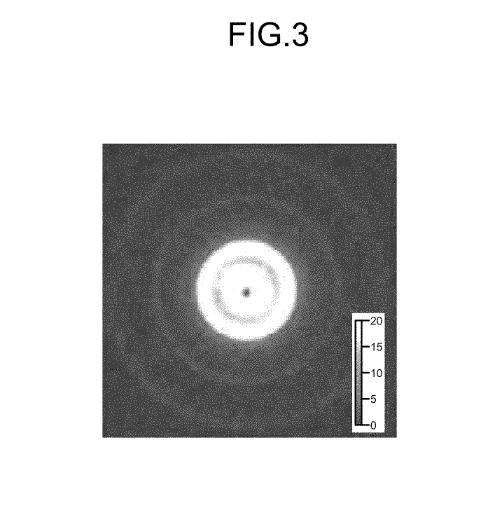

The tetrahydrofuran (THF) solutions of the diblock polymers (1) to (6) each were poured into 2 mm-square sample holders such that the concentrations of the diblock polymers (1) to (6) were 50% by mass or more and 70% by weight or less. Next, after the resultant solutions of the diblock polymers (1) to (6) were annealed at 230° C. for 24 hours, microphase separation performance was determined in a bulk state under the conditions described below, using the small-angle X-ray scattering (SAXS) analyzer of the synchrotron radiation beamline BL45XU, Spring-8 (super photon ring-8GeV) manufactured by High Energy Accelerator Research Organization. The angular dependence of scattering appearing on the small angle side by emitting X rays to the diblock polymer sample was determined by measurement for 30 minutes using an imaging plate. For measurement data processing, background correction for air scattering or the like was performed to calculate q/nm-1. After Fourier transform analysis was conducted, a half of the average repeating pattern size width (=D) of the microdomain structure formed by polymer self-assembly, that is, the numerical value of half pitch (hp) of the self-assembled film was measured. The results are listed in Table 1. FIG. 2 illustrates a data chart of SAXS (trade name: Nanoviewer manufactured by Rigaku Corporation), and FIG. 3 illustrates an optical coherence photograph.

The propylene glycol methyl ether acetate (PGMEA) solutions of the diblock polymers (1) to (3) were applied on a silicon substrate with a guide pattern to form a self-assembled film, followed by annealing at 200° C. or higher and 300° C. or lower for 5 minutes or longer to 1 hour or shorter to obtain a pattern of self-assembled microdomain structure on the silicon substrate. The pattern of microdomain structure was etched with oxygen plasma gas, resulting in a projection and depression pattern with a half pitch 10 nm or smaller and a projection and depression pattern with a half pitch of 5 nm or smaller, such as a line pattern and a contact hole pattern.

TABLE 1

| | | Molecular | Degree of | Lamellar structure |
|---|---|---|---|---|
| | Polymer | weight | distribution | (hp) |
| Example 1 | Diblock | 12,100 | 1.05 | 7.9 nm |
| | polymer (1) | | | |
| Example 2 | Diblock | 7,500 | 1.04 | 5.3 nm |
| | polymer (2) | | | |
| Example 3 | Diblock | 5,700 | 1.05 | 4.2 nm |
| | polymer (3) | | | |
| Comparative | Diblock | 30,700 | 1.05 | 10.4 nm |
| Example 1 | polymer (4) | | | |
| Comparative | Diblock | 15,200 | 1.04 | Phase separation |
| Example 2 | polymer (5) | | | not detected |
| Comparative | Diblock | 12,200 | 1.05 | Phase separation |
| Example 3 | polymer (6) | | | not detected |

In Table 1, the molecular weight refers to a weight average molecular weight. The degree of distribution refers to a molecular-weight distribution (Mw/Mn).

As can be understood from Table 1, a lamellar structure having a half pitch (hp) of 10 nm or smaller can be obtained with the diblock polymers (1) to (3) including the constituent unit of General Formula (1) above and the constituent unit of General Formula (2) above (Examples 1 to 3). By contrast, it is understood that with the diblock polymers (4) to (6) not including the constituent unit of General Formula (1) above and the constituent unit of General Formula (2) above, the half pitch (hp) exceeds 10 nm (Comparative Example 1), or phase separation does not occur (Comparative Examples 2 and 3). The reason for these results is presumably that self-assembly does not proceed because of the absence of the constituent unit of General Formula (1) above and the constituent unit of General Formula (2) above.

1. A polymer material for self-assembly comprising a polymer compound including a constituent unit of General Formula (1) below and a constituent unit of General Formula (2) below: 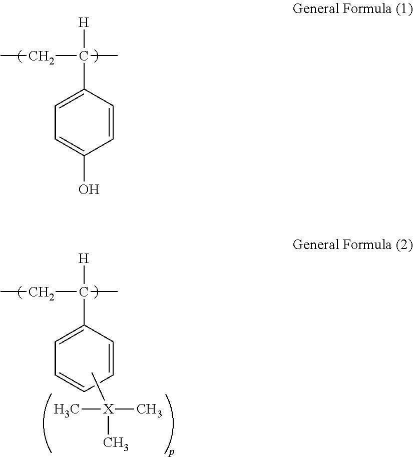
(in Formula (2), X is a carbon atom or a silicon atom, and p is an integer of 1 or more and 5 or less).

2. The polymer material for self-assembly according to claim 1, wherein the polymer compound is a diblock copolymer or a triblock copolymer of the constituent unit of General Formula (1) and the constituent unit of General Formula (2) copolymerized by living anionic polymerization.

3. The polymer material for self-assembly according to claim 1, wherein the constituent unit of General Formula (2) is represented by General Formula (3) below:

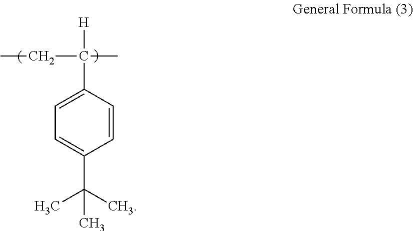

4. The polymer material for self-assembly according to claim 1, wherein the constituent unit of General Formula (2) is represented by General Formula (4) below:

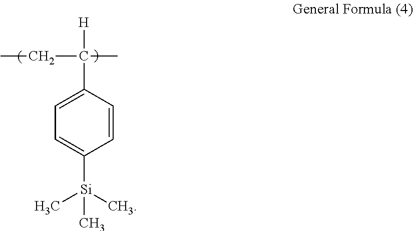

5. The polymer material for self-assembly according to claim 1, wherein the polymer compound has a weight average molecular weight of 1,000 or more and 15,000 or less.

6. A self-assembled film obtained using the polymer material for self-assembly according to claim 1.

7. A self-assembled film formed by applying a top coat agent on the self-assembled film according to claim 6.

8. A method of producing a self-assembled film, comprising forming a self-assembled film using the polymer material for self-assembly according to claim 1 any.

9. The method of producing a self-assembled film according to claim 8, wherein a self-assembled film is formed in a guide pattern.

10. The method of producing a self-assembled film according to claim 8, further comprising a step of applying a top coat agent on the self-assembled film.

11. (canceled)
